(19) United States
(12) Patent Application Publication
(10) Pub. No.: US 2010/0288631 A1
(43) Pub. Date: Nov. 18, 2010

(54) CERAMIC SPUTTERING TARGET ASSEMBLY AND A METHOD FOR PRODUCING THE SAME

(75) Inventors: Kuo-Hsien WU, Tainan (TW); Cheng-Hsin TU, Tainan (TW)

Correspondence Address: PATENTTM.US, P. O. BOX 82788, PORTLAND, OR, 97282-0788, US

(73) Assignee: SOLAR APPLIED MATERIALS TECHNOLOGY CORP., Tainan (TW)

(21) Appl. No.: 12/464,540

(22) Filed: May 12, 2009

(51) Int. Cl. C23C 14/34; B23K 1/20; B23K 31/02

(52) U.S. Cl. 204/298.13; 228/208

(57) ABSTRACT

A method for producing a ceramic sputtering target assembly has steps of providing a backing plate and forming a solder layer on a surface of the backing plate; providing a ceramic target and forming an interface layer on a surface of the ceramic target; annealing the ceramic target with the interface layer; and solder-bonding the solder layer of the backing plate and the interface layer of the ceramic target to obtain the ceramic sputtering target assembly. By annealing the interface layer made of chromium or chromium-containing alloy, the interface layer provides excellent adhesive ability to solder-bonding the solder layer and allows the ceramic target and the backing plate to be combined securely.

### BACKGROUND OF THE INVENTION

1. Field of Invention

The present invention relates to a method for producing a ceramic sputtering target assembly, and more particularly to a method for producing a ceramic sputtering target assembly with a backing plate and a ceramic sputtering target solder-bonded securely thereto.

2. Description of the Related Art

Ceramic, carbon or silicon targets are usually used for forming transparent conductive oxide film in a liquid-crystal display or in a touch panel, such as ITO film or coating layer in a hard disk, such as diamond-like carbon film.

The target is solder-bonded to a backing plate to form a sputtering target assembly. Generally in industry, the backing plate is copper and solder is indium (In), tin (Sn) or an alloy thereof having a low melting point. Because a target and a backing plate are solder-bonded at low temperature (usually below 250° C.), abnormal grain growth will not occur in the target. However, the target cannot be combined securely with the backing plate by solder bonding. Therefore, a working surface of the target, which will be solder bonded to the backing plate, is pretreated to improve properties of the working surface, so the target can be combined securely with the backing plate.

JP 2000-117427 discloses that a working surface of a target is plated with a layer of nickel (Ni) or copper to improve wetting property of the working surface because ceramic, carbon and silicon have poor wetting properties with indium and tin solder. Generally, to improve adhesive property of the working surface, a layer of molybdenum (Mo), tungsten (W), titanium (Ti), chromium (Cr) or the like, which has a thickness of less than 100 micrometers, is plated on the working surface before the layer of nickel (Ni) or copper is plated on the working surface. However, in this Japanese patent, polyvinylpyrrolidone (PVP) coating mainly containing titanium is coated on the target, which increases cost for making a sputtering target assembly.

JP 55-097472 discloses a method comprising forming a metallization layer made of alloy such as titanium-gold (Ti—Au), chromium-gold (Cr—Au) or lead-tin (Pb—Sn) on a ceramic target, bonding the ceramic target with a melted indium layer on a sputter to form a sputtering target assembly, and cooling down the sputtering target assembly to fasten the ceramic target and the indium layer. However, the method only can be used for a metallization layer with specific composition.

US 2003/0129407 discloses that a layer of titanium or chromium is sputtered on a substrate to promote adhesion between a carbon layer and the substrate.

U.S. Pat. No. 6,555,250 discloses a method for manufacturing a sputtering target assembly comprising steps of plating nickel on a surface of a metal target to form a Ni-plated target, vacuum annealing the Ni-plated target to allow for diffusion to occur between nickel and the target; and diffusion bonding the target to a backing plate. Although the target can be combined securely with the backing plate, the above method has to be proceeded at high temperature and the step of diffusion bonding is conducted under high pressure, so abnormal grain growth will probably occur in the target.

US 2009/0045051 discloses that a coupling surface is coupled to at least part of a surface of a metal target and then the target and a backing plate are diffusion bonded at high temperature. The coupling surface is made of aluminum (Al), copper, chromium, titanium or the like. The coupling surface prevents the target from being affected by high temperature and does not increase the target grain size or microstructure size.

To overcome the shortcomings, the present invention provides a method for producing a ceramic sputtering target assembly to mitigate or obviate the aforementioned.

### SUMMARY OF THE INVENTION

The primary objective of the present invention is to provide a method for producing a ceramic sputtering target assembly with a backing plate and a ceramic sputtering target solder-bonded securely thereto.

To achieve the objective, a method for producing a ceramic sputtering target assembly in accordance with the present invention comprises steps of providing a backing plate and forming a solder layer on a surface of the backing plate; providing a ceramic target and forming an interface layer on a surface of the ceramic target; annealing the ceramic target with the interface layer; and solder-bonding the solder layer of the backing plate and the interface layer of the ceramic target to obtain the ceramic sputtering target assembly.

By annealing the interface layer made of chromium or chromium-containing alloy, the interface layer provides excellent adhesive ability to solder-bonding the solder layer and allows the ceramic target and the backing plate to be combined securely.

Other objectives, advantages and novel features of the invention will become more apparent from the following detailed description when taken in conjunction with the accompanying drawings.

### BRIEF DESCRIPTION OF THE DRAWINGS

FIG. 1 is a flow chart of a method for producing a ceramic sputtering target assembly in accordance with the present invention; and

FIG. 2 is a cross sectional side view of a ceramic sputtering target assembly in accordance with the present invention.

### DETAILED DESCRIPTION OF THE INVENTION

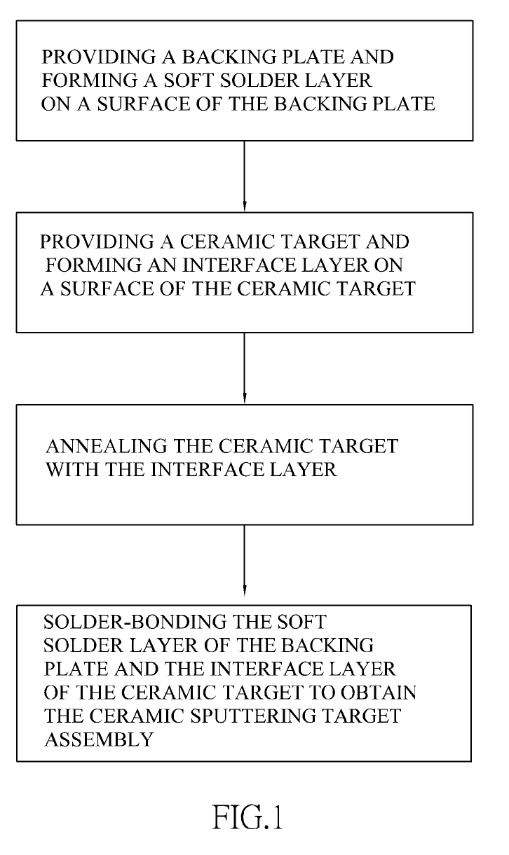

With reference to FIG. 1, a method for producing a ceramic sputtering target assembly in accordance with the present invention comprises steps of providing a backing plate (10) and forming a solder layer (11) on a surface of the backing plate (10); providing a ceramic target (20) and forming an interface layer (21) on a surface of the ceramic target (20); annealing the ceramic target (20) with the interface layer (21); and solder-bonding the solder layer (11) of the backing plate (10) and the interface layer (21) of the ceramic target (20) to obtain the ceramic sputtering target assembly.

In the step of providing a backing plate (10) and forming a solder layer (11) on a surface of the backing plate (10), the backing plate (10) is made of copper (Cu), molybdenum (Mo), titanium (Ti), aluminum (Al) or the like and the solder layer (11) is made of solder with low melting point. Preferably, the solder layer (11) is made of indium (In) or tin (Sn).

The step of providing a ceramic target (20) and forming an interface layer (21) on a surface of the ceramic target (20) comprises depositing chromium (Cr) or a chromium-containing alloy by evaporation to form an interface layer (21) with a thickness equal to or more than 1 micrometer (μm). In one aspect, the ceramic target (20) is a graphite-containing target, metallic-oxide-containing target or the like. In another aspect, the ceramic target (20) consists of indium tin oxide (ITO) or graphite.

The chromium-containing alloy is a chromium-rich alloy that has more than 50 wt % of chromium.

The step of annealing the ceramic target (20) with the interface layer (21) comprises annealing the ceramic target (20) with the interface layer (21) at 900° C.˜1500° C. under vacuum or in an inert atmosphere for less than three hours.

In the step of solder-bonding the solder layer (11) of the backing plate (10) and the interface layer (21) of the ceramic target (20), the solder-bonding technology is known by a person skilled in the art.

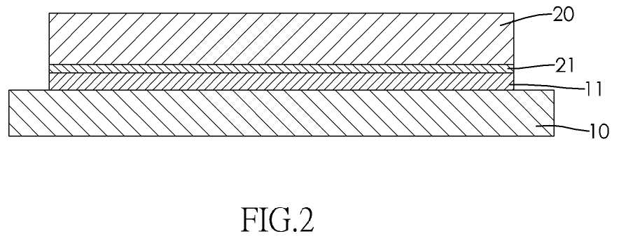

With reference to FIG. 2, a ceramic sputtering target assembly in accordance with the present invention comprises a backing plate (10) and a ceramic target (20).

The backing plate (10) is made of copper (Cu), molybdenum (Mo), titanium (Ti), aluminum (Al) or the like and has solder layer (11). The solder layer is formed on a surface of the backing plate (10). The solder layer (11) is made of low melting point solder. Preferably, the solder layer (11) is made of indium (In) or tin (Sn).

The ceramic target (20) is a graphite-containing target, metallic-oxide-containing target or the like. In another aspect, the ceramic target (20) consists of indium tin oxide (ITO) or graphite. The ceramic target (20) has an annealed interface layer (21). The annealed interface layer (21) is solder-bonded on the solder layer (11) of the backing plate (10) and is made of chromium (Cr) or chromium-containing alloy. The chromium-containing alloy is a chromium-rich alloy that has more than 50 wt % of chromium. The annealed interface layer (21) has a thickness equal to or more than 1 micrometer.

By annealing the interface layer (21) made of chromium or chromium-containing alloy, the interface layer (21) provides excellent adhesive ability for solder-bonding the solder layer (11) and allowing the ceramic target (20) and the backing plate (10) to be combined securely.

### EXAMPLE

### Example 1

A surface of a copper backing plate was coated with low-melting-point indium solder to form a solder layer, which the copper backing plate with the solder layer was heated to allow the solder layer molten (indium melting point: 156.6° C.). Pure chromium was evaporated on a surface of a graphite target to form a 1 micrometer (μm) interface layer. Then, the graphite target with the interface layer was annealed in a vacuum heater at 1200° C.˜1500° C. under 10⁻⁵ to 10⁻¹ torr for less than 3 hours. After annealing, the interface layer was tested by a peeling test with adhesive cellulose tape to make sure that no interface layer would peel off. The interface layer of the graphite target was ultrasonic wetted with molten indium solder following the previous peeling test. Finally, the interface surface with molten indium solder was solder-bonded with melted solder layer of the backing plate to form a sputtering target assembly. The sputtering target assembly then ended up with a cool down step. A shear test was conducted for testing soldering strength of the sputtering target assembly; resulting tensile shear strength was 30˜45 kg/cm².

### Example 2

A surface of a copper backing plate was coated with low-melting-point indium solder to form a solder layer, which the copper backing plate with the solder layer was heated to allow the solder layer molten (indium melting point: 156.6° C.). Pure chromium was evaporated on a surface of an ITO target to form a 1 μm interface layer. Then, the ITO target with the interface layer was annealed in a vacuum heater at 900° C.˜1100° C. under 10⁻⁵ to 10⁻¹ torr for less than 3 hours. After annealing, the interface layer was tested by the pealing test per example 1. The interface layer of the ITO target was ultrasonic wetted with molten indium solder following the previous peeling test. Finally, the interface surface with molten indium solder was solder-bonded with melted solder layer of the backing plate to form a sputtering target assembly. The sputtering target assembly then ended up with a cool down step. A shear test was conducted for testing soldering strength of the sputtering target assembly; resulting tensile shear strength was 30˜45 kg/cm².

### Example 3

A surface of a copper backing plate was coated with low-melting-point indium solder to form a solder layer, which the copper backing plate with the solder layer was heated to allow the solder layer molten (indium melting point: 156.6° C.). An alloy containing 95 wt % of chromium −5 wt % of gold was evaporated on a surface of an ITO target to form a 5 μm interface layer. Then, the ITO target with the interface layer was annealed in a vacuum heater at 900° C.˜1100° C. under 10⁻⁵ to 10⁻¹ torr for less than 3 hours. After annealing, the interface layer was tested by the pealing test per example 1. The interface layer of the ITO target was ultrasonic wetted with molten indium solder following the previous peeling test. Finally, the interface surface with molten indium solder was solder-bonded with melted solder layer of the backing plate to form a sputtering target assembly. The sputtering target assembly then ended up with a cool down step. A shear test was conducted for testing soldering strength of the sputtering target assembly; resulting tensile shear strength was 30˜45 kg/cm².

### Example 4

A surface of a copper backing plate was coated with low-melting-point tin solder to form a solder layer, which the copper backing plate with the solder layer was heated to allow the solder layer molten (tin melting point: 231.93° C.). An alloy containing 75 wt % of chromium −25 wt % of gold was evaporated on a surface of a graphite target to form a 5 μm interface layer. Then, the graphite target with the interface layer was annealed in a vacuum heater at 900° C.˜1200° C. under 10⁻⁵ to 10⁻¹ torr for less than 3 hours. After annealing, the interface layer was tested by the pealing test per example 1. The interface layer of the graphite target was ultrasonic wetted with molten indium solder following the previous peeling test. Finally, the interface surface with molten indium solder was solder-bonded with melted solder layer of the backing plate to form a sputtering target assembly. The sputtering target assembly then ended up with a cool down step. A shear test was conducted for testing soldering strength of the sputtering target assembly; resulting tensile shear strength was 30˜45 kg/cm².

### Example 5

A surface of a copper backing plate was coated with low-melting-point tin solder to form a solder layer, which the copper backing plate with the solder layer was heated to allow the solder layer molten (tin melting point: 231.93° C.). An alloy containing 51 wt % of chromium −49 wt % of gold was evaporated on a surface of a graphite target to form a 10 μm interface layer. Then, the graphite target with the interface layer was annealed in a vacuum heater at 900° C.˜1200° C. under 10⁻⁵ to 10⁻¹ torr for less than 3 hours. After annealing, the interface layer was tested by the pealing test per example 1. The interface layer of the graphite target was ultrasonic wetted with molten indium solder following the previous peeling test. Finally, the interface surface with molten indium solder was solder-bonded with melted solder layer of the backing plate to form a sputtering target assembly. The sputtering target assembly then ended up with a cool down step. A shear test was conducted for testing soldering strength of the sputtering target assembly; resulting tensile shear strength was 30˜45 kg/cm².

Even though numerous characteristics and advantages of the present invention have been set forth in the foregoing description, together with details of the structure and function of the invention, the disclosure is illustrative only. Changes may be made in detail, especially in matters of shape, size and arrangement of parts within the principles of the invention to the full extent indicated by the broad general meaning of the terms in which the appended claims are expressed.

1. A method for producing a ceramic sputtering target assembly, comprising:
providing a backing plate and forming a solder layer on a surface of the backing plate and the solder layer being made of low melting point solder;
providing a ceramic target and forming an interface layer on a surface of the ceramic target and the interface layer being made of chromium (Cr) or a chromium-containing alloy;
annealing the ceramic target with the interface layer; and
solder-bonding the solder layer of the backing plate and the interface layer of the ceramic target to obtain the ceramic sputtering target assembly.

2. The method as claimed in claim 1, wherein the ceramic target is selected from the group consisting of graphite-containing target and metallic-oxide-containing target.

3. The method as claimed in claim 1, wherein the ceramic target consists of indium tin oxide (ITO) and graphite.

4. The method as claimed in claim 1, wherein the step of annealing the ceramic target with the interface layer comprises annealing the ceramic target with the interface layer at 900° C.˜1500° C. under vacuum or in an inert atmosphere for less than three hours.

5. The method as claimed in claim 2, wherein the step of annealing the ceramic target with the interface layer comprises annealing the ceramic target with the interface layer from 900° C. to 1500° C. under vacuum or in an inert atmosphere for less than three hours.

6. The method as claimed in claim 3, wherein the step of annealing the ceramic target with the interface layer comprises annealing the ceramic target with the interface layer from 900° C. to 1500° C. under vacuum or in an inert atmosphere for less than three hours.

7. The method as claimed in claim 1, wherein the chromium-containing alloy is a chromium-rich alloy that has more than 50 wt % of chromium.

8. The method as claimed in claim 1, wherein the interface layer has a thickness equal to or more than one micrometer (μm).

9. The method as claimed in claim 1, wherein the backing plate is made of metal selected from the group consisting of copper (Cu), molybdenum (Mo), titanium (Ti) and aluminum (Al).

10. The method as claimed in claim 1, wherein the solder layer is made of metal selected from the group consisting of indium (In) and tin (Sn).

11. A ceramic sputtering target assembly comprising:
a backing plate having a solder layer being formed on a surface of the backing plate and being made of solder with low melting point;
a ceramic target having an annealed interface layer being solder-bonded on the solder layer of the backing plate and being made of chromium (Cr) or a chromium-containing alloy.

12. The ceramic sputtering target assembly as claimed in claim 11, wherein the ceramic target is selected from the group consisting of graphite-containing target and metallic-oxide-containing target.

13. The ceramic sputtering target assembly as claimed in claim 11, wherein the ceramic target consists of indium tin oxide (ITO) and graphite.

14. The ceramic sputtering target assembly as claimed in claim 11, wherein the chromium-containing alloy is a chromium-rich alloy that has more than 50 wt % of chromium.

15. The ceramic sputtering target assembly as claimed in claim 12, wherein the chromium-containing alloy is a chromium-rich alloy that has more than 50 wt % of chromium.

16. The ceramic sputtering target assembly as claimed in claim 13, wherein the chromium-containing alloy is a chromium-rich alloy that has more than 50 wt % of chromium.

17. The ceramic sputtering target assembly as claimed in claim 11, wherein the interface layer has a thickness equal to or more than one micrometer (μm).

18. The ceramic sputtering target assembly as claimed in claim 16, wherein the interface layer has a thickness equal to or more than one micrometer (μm).

19. The ceramic sputtering target assembly as claimed in claim 11, wherein the backing plate is made of metal selected from the group consisting of copper (Cu), molybdenum (Mo), titanium (Ti) and aluminum (Al).

20. The ceramic sputtering target assembly as claimed in claim 11, wherein the solder layer is made of metal selected from the group consisting of indium (In) and tin (Sn).
